(19) United States
(12) Patent Application Publication
(10) Pub. No.: US 2017/0162231 A1
(43) Pub. Date: Jun. 8, 2017

(54) MEMORY DEVICE

(71) Applicant: SK hynix Inc., Icheon-si Gyeonggi-do (KR)

(72) Inventor: Duk Su CHUN, Icheon-si Gyeonggi-do (KR)

(21) Appl. No.: 15/186,669

(22) Filed: Jun. 20, 2016

(30) Foreign Application Priority Data
Dec. 3, 2015 (KR) 10-2015-0171692

(51) Int. Cl. G11C 5/02; G11C 5/14

(52) U.S. Cl. CPC G11C 5/02; G11C 5/14

(57) ABSTRACT

A memory device may be provided. The memory device may include a plurality of channel areas including a plurality of cell array areas. The memory device may include power interconnections and capacitor areas extended between the plurality of cell array areas in the plurality of channel areas.

### CROSS-REFERENCES TO RELATED APPLICATION

The present application claims priority under 35 U.S.C. §119(a) to Korean application number 10-2015-0171692, filed on Dec. 3, 2015, in the Korean Intellectual Property Office, which is incorporated herein by reference in its entirety.

### BACKGROUND

1. Technical Field

Various embodiments may generally relate to a memory device.

2. Related Art

As the size of an electronic apparatus is reduced, there has been proposed a memory device which does not separately include memories of operation units and includes a plurality of channels capable of operating independently of each other.

However, including a plurality of channels which independently operate, results in a problem. This problem relates to space, or the lack there of it, and the necessity to ensure a space among the channels within the memory device.

### SUMMARY

In an embodiment, a memory device may include a first channel including a plurality of cell array areas arranged in a matrix form and substantially having a rectangular shape. The memory device may include a second channel including a plurality of cell array areas arranged in a matrix form and substantially having a rectangular shape to be adjacent to one side of the first channel. The memory device may include a first power interconnection extending in a first direction along the side at which the first channel and the second channel are adjacent to each other. The memory device may include a second power interconnection extended in a second direction substantially perpendicular to the first direction and extended across the first and second channels. The channels may include first and second peripheral circuits, which may be arranged at sides at which the first channel and the second channel are not adjacent to each other, while adjacent sides face each other.

In an embodiment, a memory device may be provided. The memory device may include a plurality of channel areas including a plurality of cell array areas and may be configured to operate independently of each other. The memory device may include power interconnections and capacitor areas extended between the plurality of cell array areas in the plurality of channel areas.

### BRIEF DESCRIPTION OF THE DRAWINGS

FIG. 1 is a plan view illustrating a representation of an example of a memory device according to an embodiment.

FIG. 2 is a plan view illustrating a representation of an example of a memory device according to an embodiment.

FIG. 3 is a plan view illustrating a representation of an example of an example of peripheral circuits of a memory device according to an embodiment.

FIG. 4 illustrates a block diagram of an example of a representation of a system employing a memory device with the various embodiments discussed above with relation to FIGS. 1-3.

### DETAILED DESCRIPTION

In a memory device according to various embodiments, a plurality of channels operating independently of each other may be arranged to be adjacent to each other to ensure a space between the plurality of channels. In a memory device according to various embodiments, power interconnections may be provided to allow power to be shared by the plurality of channels, so that the supply of the power may be facilitated.

In a memory device according to various embodiments, peripheral circuits may be provided at an area where a plurality of channels are not adjacent to each other and each include data and address processing units, so that the plurality of channels may perform input/output through any peripheral circuits.

In a memory device according to various embodiments, the reliability of signals transmitted/received between a plurality of channels may be ensured.

According to various embodiments, even when a plurality of channels are arranged to be adjacent to each other and power and signal interconnections are shared, the memory device may include a unit capable of compensating for power and signals, so that the size can be reduced.

According to various embodiments, in the memory device, a plurality of channels are arranged to be adjacent to each other, so that it may be possible to improve the degree of integration of the entire memory device and ensure the reliability of power supply and signal transmission and reception (transmission/reception).

Hereinafter, a memory device will be described below with reference to the accompanying drawings through various examples of embodiments.

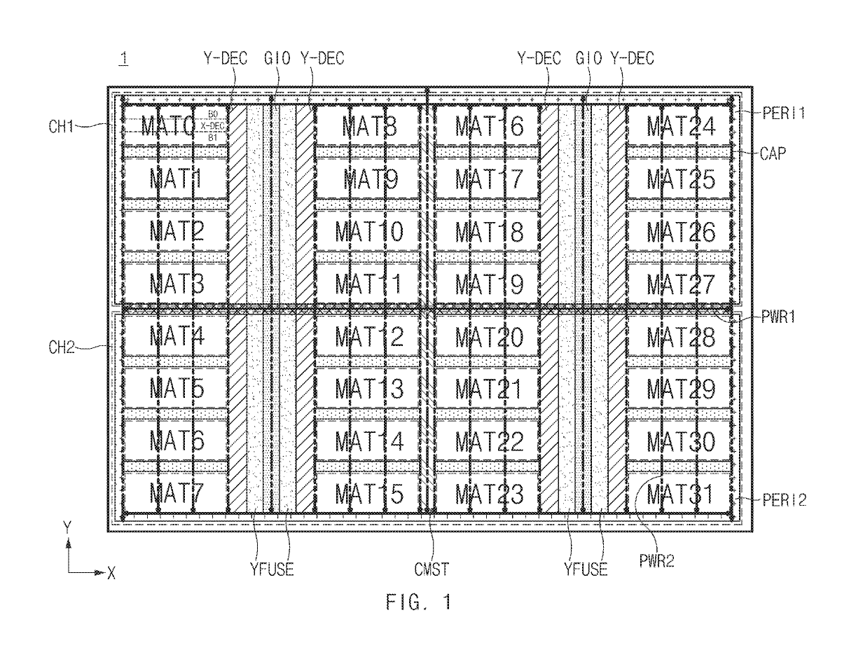

FIG. 1 is a plan view illustrating a representation of an example of a memory device according to an embodiment.

Referring to FIG. 1, a memory device 1 may include a plurality of channels CH1 and CH2 each including peripheral circuits PERI1 and PERI2, a first power interconnection PWR1 (a thick solid line), and a second power interconnection PWR2 (a thick two dot chain line).

The channels CH1 and CH2 may include a plurality of cell array areas MAT0 to MAT31 arranged in a matrix form while substantially forming a rectangular shape. The cell array areas MAT0 to MAT31 may correspond to a mat MAT of 1 M(MEGA BIT) unit including a plurality of banks and memory cells. Referring to FIG. 1, reference numerals are not written to the same area and the same hatching is used. In an embodiment, the first and second channels CH1 and CH2 include memory cells having substantially the same density.

The cell array areas MAT0 to MAT31 in the channels CH1 and CH2 may be arranged in a matrix form while being spaced apart from one another in a X direction and a Y direction. The cell array areas MAT0 to MAT31 may include memory cell blocks (B0 and B1 of the MAT0) and an X decoder (a X-DEC of MAT0) therein. FIG. 1 illustrates that Y decoders Y-DEC are arranged adjacent to an exterior of the cell array areas MAT0 to MAT31; however, the Y decoders Y-DEC may also be respectively included in the cell array areas MAT0 to MAT31.

The rectangular channels CH1 and CH2 may be arranged such that one or more sides thereof are adjacent to each other. At a side at which the channels CH1 and CH2 are adjacent to each other, the first power interconnection PWR1 may extend in the X direction. The first power interconnection PWR1 may perform a function of coupling a power supply voltage between the first channel CH1 and the second channel CH2, which share a power voltage source, thereby allowing the first channel CH1 and the second channel CH2 to receive a power supply voltage, similarly to the case in which the first channel CH1 and the second channel CH2 separately receive the power supply voltage.

The memory device may include the second power interconnection PWR2 extending in the Y direction substantially perpendicular to the X direction and extending across the first and second channels CH1 and CH2. The second power interconnection PWR2 may extend between the first peripheral circuit PERI1 included in the first channel CH1 and the second peripheral circuit PERI2 included in the second channel CH2, and may be arranged among the cell array areas MAT0, MAT1, . . . .

The first power interconnection PWR1 the second power interconnection PWR2 may be formed at an upper portion of the memory device and may be arranged to have an entire mesh shape such that the power supply voltage may be easily supplied to the entire memory device.

The first and second peripheral circuits PERI1 and PERI2 may be arranged at sides, at which the first channel CH1 and the second channel CH2 are not adjacent to each other, while facing each other.

According to an embodiment, the first and second peripheral circuits PERI1 and PERI2 may be formed at one or more sides at which the first channel CH1 and the second channel CH2 are not adjacent to each other. For example, referring to FIG. 1, when the first channel CH1 and the second channel CH2 are adjacent to each other through one side, the first peripheral circuit PERI1 may be formed at the other three sides constituting the first channel CH1. Similarly, the second peripheral circuit PERI2 may be formed at three sides of a rectangle constituting the second channel CH2.

The first and second peripheral circuits PERI1 and PERI2 included in the memory device according to an embodiment may include a circuit or processor etc., required for processing data and addresses, respectively.

In the case in which the first and second channels CH1 and CH2 have been combined with each other, when a data processor or data processing circuit and an address processor or address processing circuit are distributed to the peripheral circuits, a difference may occur in delay times required for address and data processing of each channel and also a bottleneck phenomenon may occur.

However, in the memory device according to an embodiment, the peripheral circuits PERI1 and PERI2 adjacent to the plurality of channels CH1 and CH2 each include a data processing circuit or data processor and an address processing circuit or address processor, so that the cell array areas MAT0, MAT1, . . . included in the channels CH1 and CH2 may be distributed and processed. Consequently, a deviation of a delay time required for address or data transfer can be reduced and a bottleneck phenomenon of signals can be substantially prevented from occurring.

According to an embodiment, the memory device 1 may further include capacitor areas CAP arranged among the cell array areas MAT0, MAT1, . . . , and extending in the X direction. The capacitor areas CAP may also be arranged in substantially the same area as that of the first power interconnection PWR1. In this case, the capacitor areas CAP may be formed at a height different from that of the first power interconnection PWR1 in the vertical direction. In an embodiment, the capacitor areas CAP are arranged between two adjacent sides of cell array areas (i.e., MAT 24 and MAT 25) and extending in an X direction.

The capacitor area CAP may include at least one capacitor, and is provided in order to ensure the stability of signals transferred between the first channel CH1 and the second channel CH2.

According to an embodiment, the capacitor areas CAP may be intermittently (discontinuously) arranged only in an area, where the cell array areas MAT0 and MAT1 are formed, while extending in the X direction.

In a period with no capacitor areas CAP in the X direction, Y fuse areas YFUSE extending in the Y direction may be formed. Although not illustrated in FIG. 1, the memory device may also further include X fuse areas, wherein the X fuse areas and the Y fuse areas are provided such that repair is performed for failed memory cells of the memory cells of the cell array areas MAT0 to MAT31 and the failed memory cells may be replaced with normal memory cells.

According to an embodiment, the memory device may include input/output lines GIO extending in the Y direction to perform data input/output in order to read data from the plurality of cell array areas or write data in the plurality of cell array areas.

The input/output lines GIO may be continuously formed between the first peripheral circuit PERI1 the second peripheral circuit PERI2. Furthermore, the input/output lines GIO may extend along the Y direction perpendicular to or substantially perpendicular to the period with no capacitor areas CAP in the X direction.

The memory device may include a signal compensation area CMST extending along the first channel CH1 and the second channel CH2 in the Y direction. The signal compensation area CMST may be arranged among the cell array areas MAT0 to MAT31, and may be formed at a layer of a vertical height substantially equal to that of the second power interconnection PWR2.

The signal compensation area CMST may include a capacitor and/or a repeater, thereby reducing noise of signals occurring between the first channel CH1 and the second channel CH2 and compensating for the reduction of the intensity of signals.

According to an embodiment, the signal compensation area CMST may be formed in an area adjacent to the second power interconnection PWR2. In this case, the signal compensation area CMST and the second power interconnection PWR2 may be formed at heights different from each other in the vertical direction. In an embodiment, the first and second power interconnections PWR1 and PWR2 may be formed above the input/output lines GIO. In an embodiment, the first and second power interconnections PWR1 and PWR2 may be formed at a vertical height higher than the input/output lines GIO.

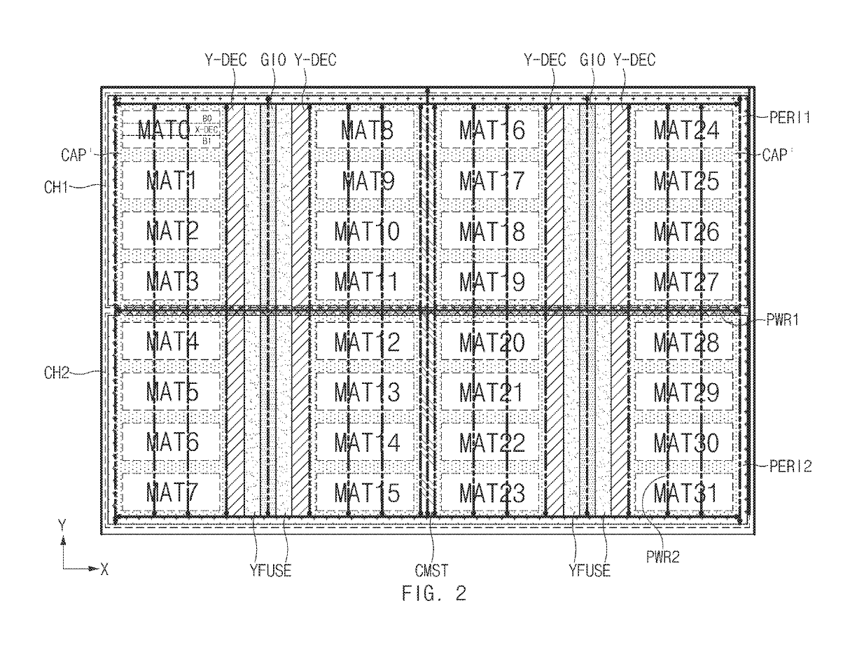

FIG. 2 is a plan view illustrating a representation of an example of a memory device according to an embodiment.

In the memory device illustrated in FIG. 2, a position, at which a capacitor area CAP′ has been formed, is different from that of the memory device illustrated in FIG. 1. Since the other elements are substantially equal to those of the memory device described with reference to in FIG. 1, a description thereof will be omitted in order to reduce redundancy.

The capacitor area CAP′ of FIG. 2 may be formed to surround the cell array areas MAT0 to MAT31. As the capacitor area CAP′ is formed to surround the cell array areas MAT0 to MAT31, it is possible to reduce noise of memory cells.

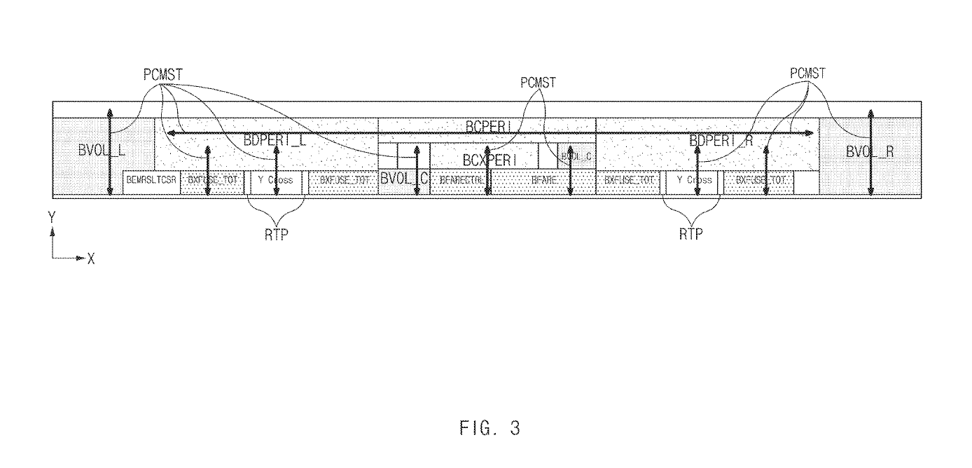

FIG. 3 is a plan view illustrating a representation of an example of an example of peripheral circuits of a memory device according to an embodiment.

The peripheral circuits illustrated in FIG. 3 may correspond to the configurations of the first and second peripheral circuits PERI1 and PERI2 of FIG. 1 and FIG. 2. In the memory device according to an embodiment, a plurality of channels may respectively include peripheral circuits having substantially the same configuration.

The peripheral circuits may include areas BDPERI_L and BDPERI_R for data input/output, areas BCPERI and BCXPERI for address control, areas BVOL_L and BVOL_R for supplying a power supply voltage, and the like.

Additionally, the peripheral circuits may further include areas BXFUSE_TOT, BFARECTRL, and BFARE for fuse control, and according to an embodiment, the peripheral circuits may include an area BEMRSLTCSR for compensating for a variation due to PVT (Pressure, Voltage, and Temperature).

According to an embodiment, the peripheral circuits may further include a repeater RTP area for compensating for the reduction of the intensity of signals.

In each area of such peripheral circuits, as all the respective peripheral circuits are coupled to each another with respect to a plurality of channels (for example, the first channel CH1 and the second channel CH2) as described above, signal interconnections increase, so that a bottleneck phenomenon becomes excessive. In order to improve such a phenomenon, compensation interconnections PCMST may be formed at an upper portion in the vertical direction as illustrated in FIG. 3 as compared with the existing signal interconnections. Arrows indicated by thick solid lines of FIG. 3 indicate the arrangement and extension directions of the compensation interconnections PCMST.

The compensation interconnections PCMST may be formed at substantially the same vertical position as those of the first and second power interconnections PWR1 and PWR2 described with reference to FIG. 1, and may extend in at least one of the first direction and the second direction.

For example, the compensation interconnections PCMST may extend in the X direction above the areas BDPERI_L and BDPERI_R for data input/output and the areas BCPERI and BCXPERI for address control. Furthermore, the compensation interconnections PCMST may extend in the Y direction above the areas BVOL_L and BVOL_R for supplying a power supply voltage. The compensation interconnections PCMST formed above the areas BVOL_L and BVOL_R for supplying a power supply voltage may be coupled to the second power interconnection PWR2 formed in the cell array areas MAT0 to MAT31 of the channels CH1 and CH2 (see FIG. 1 and FIG. 2).

According to an embodiment, the compensation interconnections PCMST formed above the areas BXFUSE_TOT, BFARECTRL, and BFARE for fuse control may extend in the X direction or the Y direction.

The compensation interconnections PCMST may distribute the functions of signal interconnections positioned below, thereby minimizing a bottleneck phenomenon. As described above, since the peripheral circuits PERI1 and PERI2 may include a data control unit and an address control unit, a plurality of interconnections may be arranged in the peripheral circuits PERI1 and PERI2 in order to process data and addresses, so that a bottleneck phenomenon may become excessive. In this regard, the memory device according to an embodiment further includes the compensation interconnections PCMST at a position higher than those of general interconnections in the peripheral circuit area in the vertical direction, so that it may be possible to attenuate a bottleneck phenomenon of signal interconnections concentrated on the peripheral circuits.

As described above, in the memory device according to an embodiment, a plurality of channels are arranged adjacent to each other and power interconnections are formed between these channels in a mesh form, so that power supply is facilitated. Additionally, a capacitor, a repeater and the like may be provided in order to remove noise due to the movement of signals and compensate for signal attenuation.

Furthermore, in the memory device according to an embodiment, peripheral circuits are provided adjacent to the channels, wherein each peripheral circuit may include data and address processing units. Accordingly, a plurality of channels may be freely coupled to a specific peripheral circuit. Moreover, in order to substantially prevent a bottleneck phenomenon from occurring in the peripheral circuits, compensation interconnections may be additionally provided above signal interconnections.

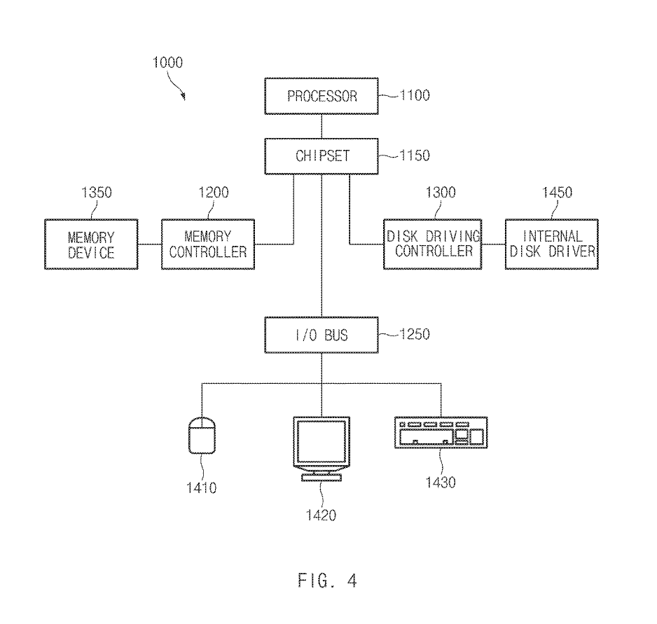

The memory device as discussed above (see FIGS. 1-3) are particular useful in the design of memory devices, processors, and computer systems. For example, referring to FIG. 4, a block diagram of a system employing a memory device in accordance with the various embodiments are illustrated and generally designated by a reference numeral 1000. The system 1000 may include one or more processors (i.e., Processor) or, for example but not limited to, central processing units (“CPUs”) 1100. The processor (i.e., CPU) 1100 may be used individually or in combination with other processors (i.e., CPUs). While the processor (i.e., CPU) 1100 will be referred to primarily in the singular, it will be understood by those skilled in the art that a system 1000 with any number of physical or logical processors (i.e., CPUs) may be implemented.

A chipset 1150 may be operably coupled to the processor (i.e., CPU) 1100. The chipset 1150 is a communication pathway for signals between the processor (i.e., CPU) 1100 and other components of the system 1000. Other components of the system 1000 may include a memory controller 1200, an input/output (“I/O”) bus 1250, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

As stated above, the memory controller 1200 may be operably coupled to the chipset 1150. The memory controller 1200 may include at least one memory device as discussed above with reference to FIGS. 1-3. Thus, the memory controller 1200 can receive a request provided from the processor (i.e., CPU) 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one memory device as discussed above with relation to FIGS. 1-3, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420, and 1430. The I/O devices 1410, 1420, and 1430 may include, for example but are not limited to, a mouse 1410, a video display 1420, or a keyboard 1430. The I/O bus 1250 may employ any one of a number of communications protocols to communicate with the I/O devices 1410, 1420, and 1430. In an embodiment, the I/O bus 1250 may be integrated into the chipset 1150.

The disk driver controller 1300 may be operably coupled to the chipset 1150. The disk driver controller 1300 may serve as the communication pathway between the chipset 1150 and one internal disk driver 1450 or more than one internal disk driver 1450. The internal disk driver 1450 may facilitate disconnection of the external data storage devices by storing both instructions and data. The disk driver controller 1300 and the internal disk driver 1450 may communicate with each other or with the chipset 1150 using virtually any type of communication protocol, including, for example but not limited to, all of those mentioned above with regard to the I/O bus 1250.

It is important to note that the system 1000 described above in relation to FIG. 4 is merely one example of a system 1000 employing a memory device as discussed above with relation to FIGS. 1-3. In alternate embodiments, such as, for example but not limited to, cellular phones or digital cameras, the components may differ from the embodiments illustrated in FIG. 4.

While various embodiments have been described above, it will be understood to those skilled in the art that the embodiments described are by way of example only. Accordingly, the memory device described herein should not be limited based on the described embodiments.

What is claimed is:

1. A memory device comprising:
a first channel including a plurality of cell array areas arranged in a matrix form and substantially having a rectangular shape;
a second channel including a plurality of cell array areas arranged in a matrix form, substantially having a rectangular shape, and adjacent to one side of the first channel;
a first power interconnection extended in a first direction along the side at which the first channel and the second channel are adjacent to each other; and
a second power interconnection extended in a second direction substantially perpendicular to the first direction and extended across the first and second channels,
wherein the first channel includes a first peripheral circuit,
wherein the second channel includes a second peripheral circuit, and
wherein the first and second peripheral circuits are arranged at sides at which the first channel and the second channel are not adjacent to each other, while adjacent sides face each other.

2. The memory device of claim 1, wherein the first channel and the second channel operate independently of each other.

3. The memory device of claim 2, further comprising:
a capacitor area arranged between each pair of adjacent cell array areas for each channel, the capacitor area extended in the first direction between each pair of the adjacent cell array areas.

4. The memory device of claim 2, further comprising:
a capacitor area arranged to surround the plurality of cell array areas.

5. The memory device of claim 2, wherein each of the first and second peripheral circuits includes data and address processing circuits.

6. The memory device of claim 5, wherein the cell array area corresponds to a cell mat MAT including a plurality of banks.

7. The memory device of claim 2, wherein the first and second channels include memory cells having substantially same density.

8. The memory device of claim 3, further comprising:
a signal compensation area extended in substantially the second direction between the cell array areas.

9. The memory device of claim 8, wherein the signal compensation area includes a repeater and a capacitor

10. The memory device of claim 9, wherein the repeater and the capacitor of the signal compensation area are configured to reduce noise of signals occurring between the first channel and the second channel.

11. The memory device of claim 2, further comprising:
input/output lines extended from the first peripheral circuit to the second peripheral circuit between the cell array areas in substantially the second direction.

12. The memory device of claim 11, wherein the first and second power interconnections are formed above the input/output lines.

13. The memory device of claim 12, wherein the first and second peripheral circuits include compensation interconnections extended in at least one of the first direction and the second direction at a vertical position substantially equal to positions of the first and second power interconnections.

14. A memory device comprising:
a plurality of channel areas including a plurality of cell array areas and configured to operate independently of each other; and
power interconnections and capacitor areas extended between the plurality of cell array areas in the plurality of channel areas.

15. The memory device of claim 14, wherein the power interconnections are formed between the plurality of cell array areas in a mesh form.

16. The memory device of claim 14, further comprising:
a peripheral circuit area formed at a side at which the plurality of channel areas are not adjacent to each other.

17. The memory device of claim 16, wherein a plurality of peripheral circuit areas are provided and each of the peripheral circuit areas includes data and address control circuits.

18. The memory device of claim 15, wherein the cell array area corresponds to a cell mat MAT including a plurality of banks.

19. The memory device of claim 15, further comprising:
a signal compensation area formed between the cell array areas.

20. The memory device of claim 19, wherein the signal compensation area includes a repeater and a capacitor.

21. The memory device of claim 20, wherein the repeater and the capacitor of the signal compensation area are configured to reduce noise of signals occurring between the first channel and the second channel.
